(19) United States
(12) Patent Application Publication
(10) Pub. No.: US 2002/0074633 A1
(43) Pub. Date: Jun. 20, 2002

(54) Interconnection of active and passive components in substrate

(76) Inventors: Lary R. Larson, Gold Canyon, AZ (US); Andreas Armin Fenner, Chandler, AZ (US)

Correspondence Address: Girma Wolde-Michael, Medtronic, Inc., MS 301, 7000 Central Avenue NE, Minneapolis, MN, 55432, US

(21) Appl. No.: 09/740,079

(22) Filed: Dec. 18, 2000

(51) Int. Cl. H01L 23/02

(52) U.S. Cl. 257/678

(57) ABSTRACT

Interconnection of active and passive components in a substrate built using wafer fabrication techniques increase routing density by using a silicon substrate and using silicon processing technologies to embed interconnects and components into the substrate. Implantable medical devices including surge protection, output transistors, and other high power components are interconnected using the substrates.

### FIELD OF THE INVENTION

The present invention relates generally to connecting active and passive components, and more specifically to connecting active and passive components using substrates built with semiconductor wafer processing technologies. The components are preferably conducive to application in medical devices.

### BACKGROUND OF THE INVENTION

In conventional integrated circuits, increasing complexity of layouts and shrinking sizes of components and devices contribute to problems with conventional technology in interconnecting components in the circuits. The problems include the complexity of interconnects and current dimensions of such interconnects, which limit the routing densities of components. Current substrates do not allow for small enough feature sizes to adequately reduce the size of interconnects. As device sizes get smaller and smaller, and as more and more devices are placed into apparatuses, the many interconnects actually limit routing density. It would therefore be desirable to reduce feature size of interconnects in various application systems. This is particularly favorable to implantable medical devices in reducing size and volume.

Traditional ceramic substrates allow for the use of interconnects only down to a certain feature size. Currently, this feature size is approximately 5 mils for lines, with 5 mils for spaces between lines. This size is large enough that a great deal of available space and real estate in integrated circuits using ceramic substrates is consumed by the interconnects. Densities of integrated circuit layouts in all areas, and especially in the implantable medical device and hearing aid areas, where the size of devices is a significant design factor, are continuing to increase. It would be desirable to reduce further the size of interconnect lines and spaces.

Because of the large feature size and required real estate for interconnects on ceramic substrates, the limiting factor in reducing size of implantable medical devices and hearing aids using ceramic substrates is the substrates themselves. As more and more components are required or desired in such devices, they cannot be reduced in size beyond the size required for interconnects on the ceramic substrates.

Multi chip module deposited (MCMD) technology does allow for the reduction of feature size in integrated circuits. However, such technology is not conducive to the intention of devices integrated into a substrate.

Further, active substrates are known. For example, U.S. Pat. No. 5,534,465 discloses the use of an active substrate upon which is mounted integrated circuits. Also, isolated components for interconnecting the integrated circuits are formed within the substrate. The integrated components are connected to the integrated circuits through routing interconnects on the surface of the substrate. The circuit components are interconnected only by the paths interconnecting the integrated circuits.

In implantable medical devices, it would be desirable to use a substrate that can be used as an interconnect medium. Specifically, it would be desirable to accommodate on a substrate an integrated set of active and passive components in implantable medical devices.

### SUMMARY OF THE INVENTION

In one embodiment, a method of interconnecting active and passive components in a substrate includes forming a plurality of passive components embedded in the substrate, forming a plurality of active components on the substrate, and forming a plurality of interconnects in the substrate to connect the active and the passive components. Following the formation of the components, the active and passive components are connected using the interconnects.

In another embodiment, a method of increasing routing density in a substrate includes embedding a number of passive components and a plurality of interconnects within a silicon substrate, forming a number of active components in the substrate using different geometry than that used for forming the number of passive components, and interconnecting the active and the passive components in the substrate using the interconnects.

In yet another embodiment, a substrate includes a silicon wafer having a number of passive components formed in the wafer, a number of interconnects formed to connect the passive components and at least one integrated circuit, and at least one integrated circuit interconnected to the passive components with the interconnects.

In still another embodiment, an implantable medical device includes a device body, a substrate such as the substrate described above, and other components for pacing applications.

Other embodiments are described and claimed.

### BRIEF DESCRIPTION OF THE DRAWINGS

FIG. 1 is a perspective view of a substrate according to one embodiment of the present invention;

FIGS. 2A, 2B, and 2C are top views of a substrate build process in various stages according to another embodiment of the present invention;

FIG. 3 is a perspective view of an implantable medical device according to on embodiment of the present invention;

FIG. 4 is a flow chart diagram of a method according to another embodiment of the present invention; and

FIG. 5 is a flow chart diagram of a method according to another embodiment of the present invention.

### DETAILED DESCRIPTION OF THE DRAWINGS

In the following detailed description of the embodiments, reference is made to the accompanying drawings which form a part hereof, and in which is shown by way of illustration specific embodiments in which the invention may be practiced. It is to be understood that other embodiments may be utilized and structural or logical changes may be made without departing from the scope of the present invention.

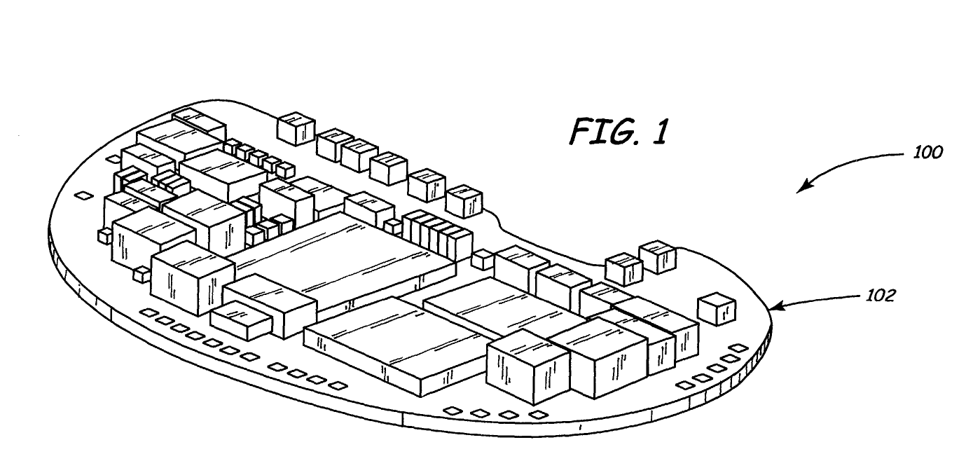

In one embodiment 100 shown in FIG. 1, a semiconductor substrate 102 is built up with both active and passive components which are interconnected in the substrate itself. In order to accomplish this interconnection within the substrate itself, the substrate is in one embodiment silicon. Silicon is the substrate of choice for the manufacture and assembly of integrated circuit devices, and implantation of known technology for working with silicon substrates allows very small feature sizes for routing interconnects and the like in the substrate itself. When the substrate 102 is built using semiconductor processing technologies, the interconnect sizes are greatly reduced.

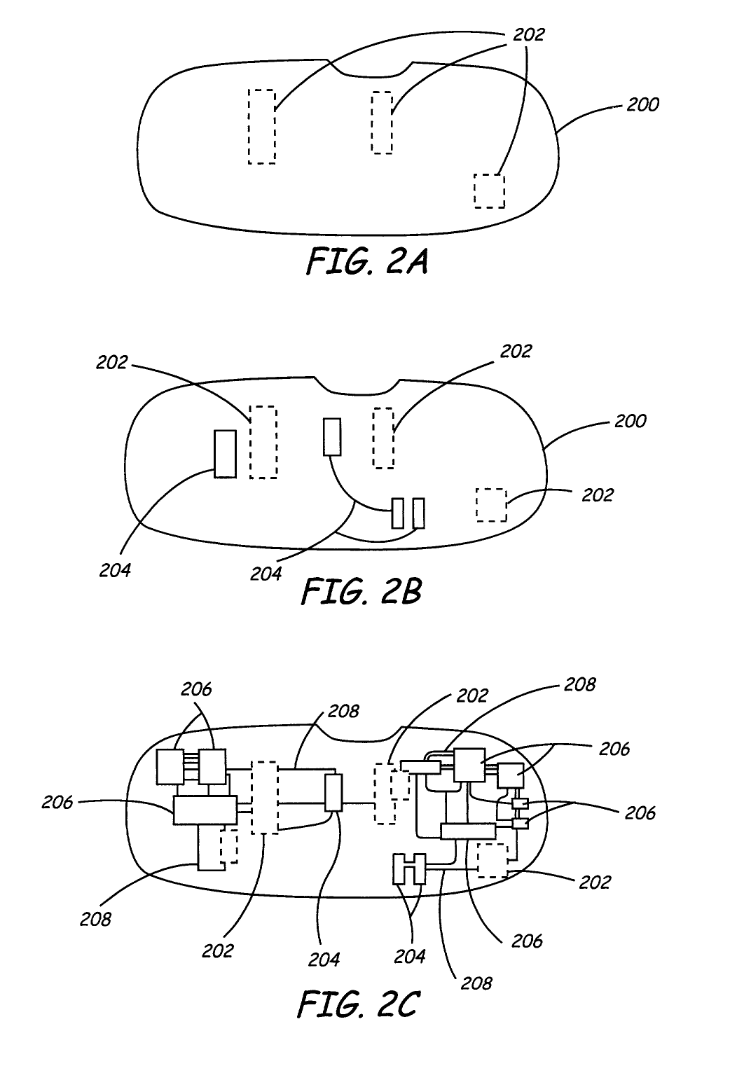

Fabrication of a semiconductor substrate such as substrate 102, incorporating active and passive technologies, as well as in-substrate interconnects, is shown in more detail in FIGS. 2A, 2B, and 2C. In pacemaker technology, pacing devices require, among other circuitry and components, output transistors, surge protection circuitry, telemetry, and pacing circuitry.

In FIG. 2A, initial fabrication of a substrate 200 having passive components such as capacitors and resistors 202 built into the substrate is shown. Such passive components are in one embodiment built into the substrate using standard semiconductor technologies such as poly and Chromium Silicon (CrSi) for resistors. Additionally, larger capacitors are built in one embodiment using micro electro mechanical systems (MEMS) technology such as deep trenching, in order to create larger capacitance values.

Once passive components such as resistors and capacitors 202 are formed in the substrate, large scale geometries are used to fabricate output transistors and surge protection devices 204 in the substrate. The use of large geometry fabrication provides large breakdown voltages and low defect rates for such components. Often, surge protection devices operate at high voltages, and therefore require large breakdown voltages. Output transistors also require high voltage and need surge protection. Once the higher voltage devices are fabricated into the substrate, additional circuitry such as pacing circuitry and the like, which is typically lower voltage circuitry, is formed external to the substrate on separate chips.

In current technology, most surge protection devices and output transistors are formed on the same chip as the rest of the pacing circuitry. This restricts the sizes and geometries available for the fabrication of pacing circuitry and the like, and reduces the ability to fabricate more sensitive circuitry with lower breakdown voltages and the like. In one embodiment, the pacing circuitry is fabricated off substrate on separate chips using smaller geometries than the surge protection devices and output transistors, allowing smaller breakdown voltages for those circuits.

In FIG. 2C, pacing circuitry and integrated circuits 206 are mounted to the substrate 102 and interconnected to the output transistors and surge protection devices 204, and to the passive components 202, via interconnects 208. The interconnects 208 are formed in the substrate 200 itself. In this embodiment, the silicon substrate 200 allows the interconnects 208 to be formed using processes for working with silicon. These processes, as has been discussed herein, allow for the reduction of feature size of the interconnects, and improve routing density in the substrate 200.

In defibrillation applications, other high power and high voltage devices are also used. Such high power and high voltage devices are also amenable to fabrication in silicon substrates. In one embodiment, high power and high voltage devices are built into the substrate using standard semiconductor wafers made from silicon or using silicon on insulator (SOI), silicon on sapphire (SOS), quartz, sapphire, or any other suitable substrate technology that can be processed by using wafer fabrication methods.

Flip chip integrated circuit solder bumps are used in one embodiment for mounting the integrated circuit chips to the substrate 200. With large feature sizes of interconnects in traditional substrates, flip chip solder bumps and pads are fairly large to ensure proper connection of integrated circuits to the substrate and any interconnects. With reduced feature size of interconnects, the size of the solder bumps used in flip chip mounting of the may also be reduced. This allows for a smaller pitch between pads without affecting reliability due to matching thermal coefficients.

In yet another embodiment, individual different circuits are built in individual processes. Such circuits include, in one embodiment, circuits formed using different processes, such as memory chips, processors, and the like. Also, a substrate with built in interconnects suitable for interconnecting various components, as well as with built in passive components, is separately formed. The circuits and the processes for fabricating the individualized chips are then built in one embodiment using the best known practices for the individual chips, instead of building them on the same silicon. Each device is therefore manufactured efficiently using best practices, and then mounted to the silicon substrate and interconnected using the interconnects and passive components built into the substrate.

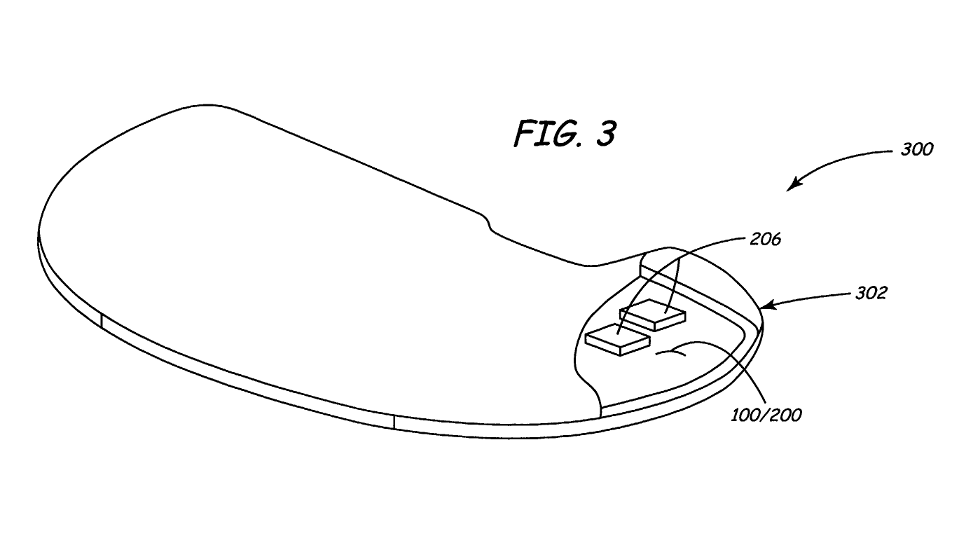

An embodiment of an implantable medical device 300 is shown in FIG. 3. Implantable medical device 300 comprises a body 302 housing medical device components including by way of example only and not by way of limitation substrates such as the substrates 100 and 200 described herein, batteries, shielding, antenna and telemetry devices and components, control circuitry, high power circuits, integrated circuits such as circuits 206, and the like. In one embodiment, the integrated circuits are formed separately from the substrate, and are interconnected using interconnects built into the substrate during wafer processing of the substrate. In another embodiment, the circuits are flip chip circuit components.

In another embodiment, the use of the semiconductor processing techniques and methods described above are used to integrate high-power components such as silicon controlled rectifiers (SCRs), metal oxide semiconductor field effect transistors (MOSFETs), other field effect devices, diodes, insulated gate bipolar transistors (IGBTs), and the like into an interconnect substrate. Such high power components are in various embodiments implemented in hearing aids, pacing devices, defibrillators, and the like.

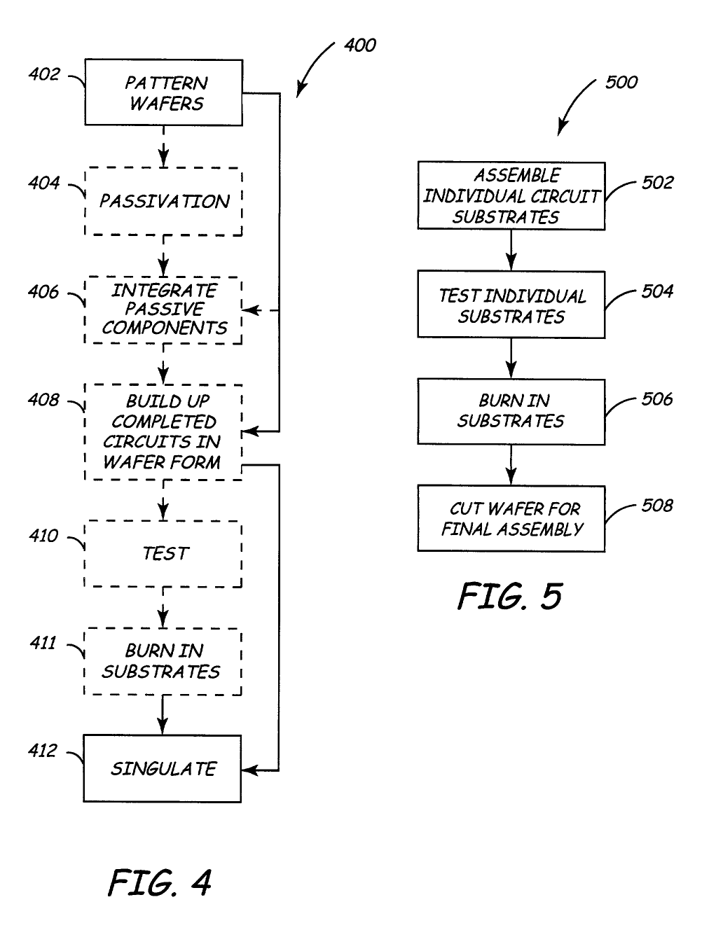

A flow chart diagram of an embodiment of a method 400 for interconnecting active and passive components in a substrate built using semiconductor wafer processing is shown in FIG. 4. For most applications, a silicon semiconductor wafer is the starting material. However any other wafer material, such as silicon on insulator (SOI), silicon on sapphire (SOS), sapphire, or quartz may be used without departing from the scope of the invention.

In one embodiment, the wafers are patterned in block 402 using standard semiconductor wafer processing technologies using either reticles or masks to pattern the desired circuits and interconnects. This may consist of as few as two layers for an interconnect only substrate, where one of the layers defines the metal such as aluminum or copper, and the other defines openings in the passivation placed on top of the metal used to attach other components such as integrated circuits (ICs), capacitors, and resistors. In one embodiment, those components are solderable, such as flip chip ICs.

Aluminum or other non-solderable metals are used in other embodiments. In those embodiments, the wafer has another metalization placed on top of the opening defined in the passivation in optional block 404 in order to be able to solder components to those areas. These metalizations are commonly known as under-bump metalizations (UBM), and are generally used to make IC pads solderable. The passivation serves to protect the non-solder areas from corrosion and soldering similar to a solder mask used for other substrates such as printed wiring boards (PWBs).

Other methods and techniques for attaching components to substrates include in various embodiments the use of conductive epoxies or z-axis epoxies instead of flip chip type or wire bond type mounting. To integrate capacitors, resistors, and/or semiconductors in further embodiments, additional mask or reticle layers are required in further optional block 406.

In another embodiment, to increase density, the top and the bottom side of the wafer are patterned with interconnects and/or embedded active/passive devices and connected through the wafer using through-wafer vias.

The completed circuits are then built up in wafer form in block 408. The wafer is in one embodiment similar to a panelized printed wiring board (PWB). Optionally, the assembly is tested in block 410, and the individual substrates are singulated in block 412. As has been disclosed herein, the substrates are, in one embodiment, burned in (optional block 411) before singulation.

In another embodiment, the substrates are singulated before assembly, testing, or burn in. The substrates are singulated into standard dice in various embodiments by standard wafer dicing techniques, scribing, or by shaping in order to fit the particular medical device or hearing aid application using laser cutting or deep reactive ion etch (RIE) in such fashion as to fit the contour of a pacemaker case of to fit inside a hearing aid body. Such freeform cutting of substrates is described in greater detail in U.S. Patent application entitled FREEFORM SUBSTRATES AND DEVICES, filed Dec. 6, 2000, assigned to the assignee of the present application, and is incorporated by reference herein in its entirety.

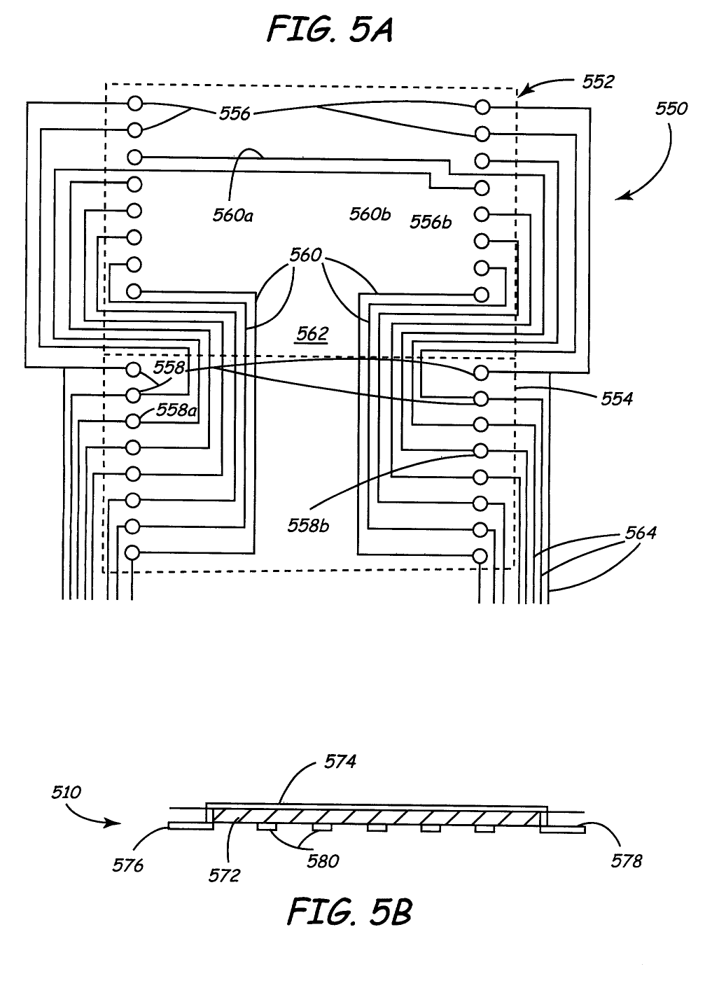

In another embodiment, a method 500 for testing fabricated wafers is shown in flow chart diagram in FIG. 5. Method 500 for burning an electrical test in wafer form comprises assembling a set of individual circuit substrates on a semiconductor wafer in block 502, testing the individual substrates in block 504, burning in the substrates in block 506, and cutting the wafer for final assembly in block 508. In one embodiment, the assembly of components such as integrated circuits to the substrates is accomplished while the substrates are still in wafer form. This allows the use of automated wafer handling equipment already available for use.

Some advantages of the substrates of the present invention embodiments include by way of example only and not by way of limitation, ease of manufacture, reduced or equal capital cost for improved product, ability to use existing equipment and processes for formation of devices and substrates, use of existing apparatuses for handling of wafers, assembly of substrates and components to substrates while in wafer form before singulation of substrates, the ability to test and burn in multiple substrates before dicing or scribing and breaking a fabricated wafer, and the like.

For example, methods and apparatuses for silicon device fabrication are known in the art. The processes for fabricating the devices to be formed into the substrates of the present invention are well established. Since the processes are well established, the equipment and requirements for fabrication using silicon are also well established. In many fabrication operations, existing equipment is usable with the methods and processes described herein to fabricate the products described.

Existing fabrication processing tools and methods are amenable to making the substrates and interconnects described in the embodiments herein. Therefore, the capital costs for implementing the methods are small compared to retooling lines for a process using new technology. Further, assembly in one embodiment is performed while the substrates are still in wafer form, and existing equipment designed for automated handling of wafers may be utilized.

While the various embodiments of the present invention have been described herein mainly with respect to implantable medical devices, the concepts and embodiments of the processes and apparatuses are amenable also to use in the hearing aid industry and similar medical devices. The hearing aid industry is faced with an increasing number of components desired or required to be placed in a limited real estate of a hearing aid body. Further, the hearing aid industry has been moving steadily to smaller and smaller devices, such as implantable hearing aid devices and the like, in which any real estate is at a high premium. The new substrates and processes, as well as the incorporation of high power and passive components into the substrate, benefit any device in which real estate needs to be conserved.

It is to be understood that the above description is intended to be illustrative, and not restrictive. Many other embodiments will be apparent to those of skill in the art upon reading and understanding the above description. The scope of the invention should, therefore, be determined with reference to the appended claims, along with the full scope of equivalents to which such claims are entitled.

What is claimed is:

1. A method of interconnecting active and passive components in a substrate, comprising:
forming a plurality of passive components embedded in the substrate;
forming a plurality of active components on the substrate;
forming a plurality of interconnects in the substrate to connect the active and the passive components; and
connecting the active and passive components with the interconnects.

2. The method of claim 1, wherein the active and the passive components are formed with different size geometries.

3. The method of claim 1, wherein the passive components are formed with standard semiconductor processing technology, and wherein the active components are formed with large scale geometries.

4. The method of claim 1, wherein forming the plurality of active components includes forming at least one surge protection device and at least one output transistor.

5. The method of claim 1, and further comprising:
forming pacing circuitry; and
connecting the pacing circuitry to the substrate interconnects and to the passive and active components via the interconnects.

6. A method of increasing routing density in a substrate, comprising:
embedding a plurality of passive components and a plurality of interconnects within a silicon substrate;
forming a plurality of active components in the substrate using a different geometry than that used for forming the plurality of passive components; and
interconnecting the active and the passive components in the substrate using the interconnects.

7. A method of testing substrates on a wafer, the method comprising:
assembling a set of individual circuit substrates on a semiconductor wafer;
testing the individual substrates;
burning in the substrates; and
cutting the wafer for final assembly.

8. The method of claim 7, wherein assembling is performed with the substrates in wafer form.

9. The method of claim 7, wherein testing is performed with the substrates in wafer form.

10. The method of claim 7, wherein burning in the substrates is performed with the substrates in wafer form.

11. A method for interconnecting active and passive components in a substrate, comprising:
pattering desired integrated circuits and interconnects in the substrate;
forming the integrated circuits and the interconnects into the substrate; and
integrating components into the substrate using additional masking layers.

12. A method of forming active and passive components in a substrate, the method comprising:
patterning a plurality of substrates on a wafer;
patterning a plurality of active and passive components on the substrates;
building the patterned components into the substrate;
interconnecting the passive and the active components in the substrate; and
singulating the substrates.

13. The method of claim 12, wherein interconnecting comprises:
forming a plurality of interconnects in the substrate for connection of the passive and the active components.

14. The method of claim 12, wherein building the patterned components comprises:
using different geometries for building the active and the passive components.

15. The method of claim 12, and further comprising:
testing the wafer substrates before singulating.

16. The method of claim 12, wherein different geometries are used to pattern the active and the passive components.

17. A substrate, comprising:
a silicon wafer having a plurality of passive components formed therein;
a plurality of interconnects formed to connect the passive components and at least one integrated circuit; and
the at least one integrated circuit interconnected to the passive components in the interconnects.

18. The substrate of claim 17, and further comprising:
a plurality of active components formed in the silicon wafer.

19. The substrate of claim 18, wherein the plurality of active components includes at least one high power component.

20. The substrate of claim 18, wherein the plurality of active components includes at least one surge protection device.

21. The substrate of claim 18, wherein the plurality of active components includes at least one output transistor.

22. The substrate of claim 17, and further comprising:
pacing circuitry mounted to the silicon wafer and interconnected to the passive and active components via the interconnects.

23. The substrate of claim 17, and further comprising:
a plurality of high power components built using different geometries than the passive components.

24. A substrate for an implantable medical device, comprising:
a silicon body;
a plurality of components embedded in the body;
a plurality of interconnects embedded in the body;
at least one surge protection device formed in the substrate; and
at least one output transistor formed in the substrate.

25. An implantable medical device, comprising:
a body;
a substrate, the substrate comprising:
a silicon wafer having a plurality of passive components formed therein;
a plurality of interconnects formed to connect the passive components and at least one integrated circuit; and
at least one integrated circuit interconnected to the passive components with the interconnects.

26. The implantable medical device of claim 25, wherein the substrate further comprises:
a plurality of active components formed in the silicon wafer.

27. The implantable medical device of claim 26, wherein the plurality of active components includes at least one high power component.

28. The substrate of claim 26, wherein the plurality of active components includes at least one surge protection device.

29. The implantable medical device of claim 26, wherein the plurality of active components includes at least one output transistor.

30. The implantable medical device of claim 25, and further comprising:
pacing circuitry mounted to the silicon wafer and interconnected to the passive and active components via the interconnects.

31. The implantable medical device of claim 25, and further comprising:
a plurality of high power components built using different geometries than the passive components.
